(19) United States
(12) Patent Application Publication
(10) Pub. No.: US 2009/0124037 A1
(43) Pub. Date: May 14, 2009

(54) METHOD OF PREVENTING COLOR STRIATION IN FABRICATING PROCESS OF IMAGE SENSOR AND FABRICATING PROCESS OF IMAGE SENSOR

(75) Inventor: Cheng-Hung Yu, Kaohsiung City (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/939,326

(22) Filed: Nov. 13, 2007

(51) Int. Cl. H01L 31/0232

(52) U.S. Cl. 438/70; 257/E31.127

(57) ABSTRACT

A fabricating process of an image sensor is provided. A substrate having thereon a circuit of the image sensor and an insulating layer is provided, wherein the insulating layer has therein a pad opening exposing a metal pad of the circuit. A filling layer is formed in the pad opening, and a color filter array is formed over the insulating layer. A planarization layer is formed over the substrate covering the color filter array, and a microlens array is formed on the planarization layer. The filling layer is then removed.

### BACKGROUND OF THE INVENTION

1. Field of Invention

This invention relates to fabrications of image sensors, and more particularly relates to a method of preventing color striation in a fabricating process of an image sensor and to a fabricating process of an image sensor.

2. Description of Related Art

Image sensor chips are core elements of digital image-recording apparatuses. An image sensor typically includes an array of photosensing devices, a circuitry coupled with the devices, a color filter array and a microlens array. The photosensing devices in a CCD image sensor are charge-coupled devices, and those in a CMOS image sensor are photodiodes.

FIG. 1 illustrates a part of a conventional fabricating process of an image sensor. The substrate 100 includes photosensing devices and a possible interconnect structure. After the upmost interconnect layer including lines 110a and a metal pad 110b is formed on the substrate 100, an insulating layer 120 is formed and then patterned to form a pad opening 122 therein exposing the metal pad 110b. A color filter array 140 is then formed on the insulating layer 120 over the lines 110a.

Because the color filter array 140 is formed after the pad opening 122 is formed and the pad opening 122 is usually 6000-8000 angstroms deep, color striation is caused due to the poor uniformity of the color (R/G/B) coating caused by the large step height difference of the pad opening 122, thus lowering the accuracy of image recording.

### SUMMARY OF THE INVENTION

This invention provides a method of preventing color striation in a process of fabricating an image sensor wherein a color filter array is formed after a pad opening is formed in an insulating layer to expose a metal pad of a circuit of the image sensor.

This invention also provides a process of fabricating an image sensor that utilizes the method of preventing color striation of this invention.

The method of preventing color striation of this invention includes forming a filling layer in the pad opening before the color filter array is formed, wherein the filling layer is removed after the color filter array is formed.

The process of fabricating an image sensor of this invention is described below. A substrate with a circuit of the image sensor and an insulating layer thereon is provided, wherein the insulating layer has therein a pad opening that exposes a metal pad of the circuit. A filling layer is formed in the pad opening, and a color filter array is formed over the insulating layer. A planarization layer is formed over the substrate covering the color filter array, and a microlens array is formed on the planarization layer. The filling layer is then removed.

Since a filling layer is formed in the pad opening before the color filter array is formed, the formation of the color filter array is not affected by a step height difference caused by the pad opening, thus preventing formation of color striation.

It is to be understood that both the foregoing general description and the following detailed description are exemplary, and are intended to provide further explanation of the invention as claimed.

### BRIEF DESCRIPTION OF THE DRAWINGS

FIG. 1 illustrates a part of a conventional fabricating process of an image sensor.

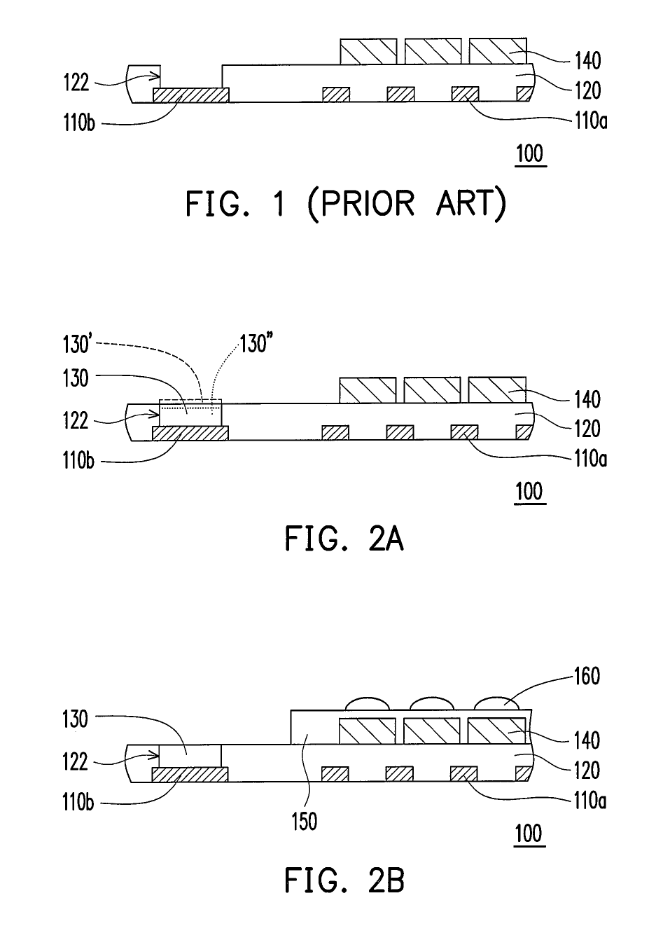

FIGS. 2A-2D illustrate a process of fabricating an image sensor according to an embodiment of this invention.

### DESCRIPTION OF EMBODIMENTS

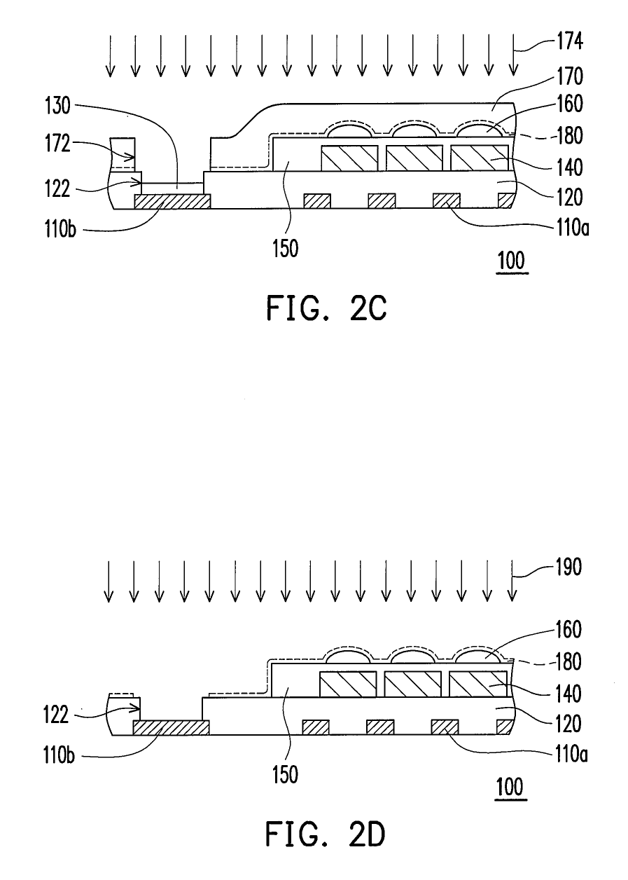

This invention is further explained with the following embodiment in reference of FIGS. 2A-2D, which is however not intended to limit the scope of this invention.

Referring to FIG. 2A, a substrate 100 is provided, including photosensing devices and a possible interconnect structure that are not shown here as being known to one of ordinary skill in the art. When the image sensor is a CMOS image sensor, for example, the photosensing devices are photodiodes and the total number of interconnect layers is usually 2. An upmost interconnect layer that includes lines 110a and a metal pad 110b has been formed on the substrate 100, and an insulating layer 120 has been formed over the substrate 100 covering the upmost interconnect layer and has been patterned to form a pad opening 122 therein exposing the metal pad 110b. The material of the upmost interconnect layer may be aluminum. The insulating layer 120 is usually a composite layer that includes a planarization layer and a passivation layer at least, as known in the prior art, wherein the planarization layer is formed to planarize the uneven surface caused by the lines 110a for the quality of the color filter array formed later, and the passivation layer may include silicon nitride.

Then, a filling material is filled in the pad opening 122 to form a filling layer 130 having a top surface coplanar with that of the insulating layer 120, a filling layer 130′ having a top surface higher than that of the insulating layer 120 or a filling layer 130″ having a top surface lower than that of the insulating layer 120. The height difference between the top surfaces of the filling layer 130′/130″ and the insulating layer 120 is preferably no more than 20% of the depth of the pad opening 122 that is usually 6000-8000 angstroms. It is particularly noted that only the case of the filling layer 130 is mentioned below and shown in the following figures because the process of the case of the filling layer 130′ or 130″ is substantially the same as the former.

In addition, the filling material may be a negative photoresist material, which may be an acrylic-like resin with a solvent selected from ethylethoxypropionate (EEP), propyleneglycol methyl ether (PGME) and propyleneglycol monomethyl ether acetate (PGMEA). The filling material can be the material of the planarization layer formed later as the base layer of a microlens array, or the material of the planarization layer in the insulating layer 120.

After the filling layer 130 is formed in the pad opening 122, a color filter array 140 is formed over the insulating layer 120. The color filter array 140 may include red, green and blue color filters that are usually formed with three color coating-patterning cycles for the three colors. Since the step height difference of the pad opening 122 has been much reduced by the filling layer 130, a coated color film has a uniform thickness and can be defined well to prevent color striation.

Referring to FIG. 2B, a planarization layer 150 is formed over the substrate 100 covering the color filter array 140. The material of the planarization layer 150 may be a negative photoresist material, and may be the same as the filling layer 130 formed in the pad opening 122. A microlens array 160 is then formed on the planarization layer 150 for focusing light to respective photosensing devices (not shown). The material for forming the microlens array 160 may be a positive photoresist material.

Referring to FIG. 2C, a patterned photoresist layer 170 is formed over the substrate 100, having an opening 172 therein exposing the filling layer 130. Referring to FIGS. 2C and 2D, the filling layer 130 is etched away with the patterned photoresist layer 170 as a mask possibly through plasma etching 174, and the photoresist layer 170 is removed successively. Then, a solvent can be applied to clear the etching residue. The plasma etching 174 may include two times of conventional De-scum etching using oxygen plasma, and the cleaning solvent may be N-methylpyrrolidinone (NMP).

It is noted that a protection layer 180 may be formed over the substrate 100 after the microlens array 160 is formed but before the patterned photoresist layer 170 is formed, so as to prevent the microlens array 160 from being damaged in the process of clearing the patterned photoresist layer 170. The portion of the protection layer 180 exposed in the opening 172 has to be removed with a suitable etchant before the filling layer 130 is removed. The protection layer 180 preferably includes a material that can be deposited at a temperature below 200° to protect the microlenses of a thermoplastic material from damage. An example of such materials is low-temperature oxide (LTO).

Moreover, in a case where a protection layer 180 is formed before the patterned photoresist layer 170, the plasma etching 174 can be set at an ordinary condition for photoresist removal. In a case where no protection layer 180 is formed, the plasma etching 174 preferably sets the oxygen plasma at a sufficiently low temperature and a sufficiently short RF time such that the microlenses 160 are not damaged. The low temperature is about 200° C. and the short RF time is about 20 seconds, for example.

Since a filling layer is formed in the pad opening before the color filter array is formed, the formation of the color filter array is not affected by a step height difference caused by the pad opening, thus preventing formation of color striation and improving the accuracy of image recording.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A method of preventing color striation in a fabricating process of an image sensor where a color filter array is formed after a pad opening is formed in an insulating layer to expose a metal pad of a circuit of the image sensor, comprising forming a filling layer in the pad opening before the color filter array is formed, wherein the filling layer is removed after the color filter array is formed.

2. The method of claim 1, wherein a top surface of the filling layer is coplanar with a top surface of the insulating layer.

3. The method of claim 1, wherein a top surface of the filling layer is higher or lower than a top surface of the insulating layer.

4. The method of claim 3, wherein a height difference between top surfaces of the filling layer and the insulating layer is no more than 20% of a depth of the pad opening.

5. The method of claim 1, wherein the filling layer comprises a material of a planarization layer that will be formed covering the color filter array.

6. The method of claim 1, wherein the filling layer comprises a negative photoresist material.

7. The method of claim 1, wherein the image sensor is a CMOS image sensor.

8. A process of fabricating an image sensor, comprising:
providing a substrate having a circuit of the image sensor and an insulating layer thereon, wherein the insulating layer has therein a pad opening exposing a metal pad of the circuit;
forming a filling layer in the pad opening;
forming a color filter array over the insulating layer;
forming a planarization layer over the substrate covering the color filter array;
forming a microlens array on the planarization layer; and
removing the filling layer.

9. The process of claim 8, wherein removing the filling layer comprises:
forming a protection layer over the substrate covering the microlens array;
forming a patterned photoresist layer over the substrate exposing a portion of the protection layer over the filling layer;
etching away the portion of the protection layer and the filling layer with the patterned photoresist layer as a mask; and
removing the patterned photoresist layer while the protection layer protects the microlens array.

10. The process of claim 9, wherein the protection layer comprises low-temperature oxide (LTO).

11. The process of claim 8, wherein removing the filling layer comprises:
forming a patterned photoresist layer over the substrate exposing the filling layer;
etching away the filling layer with the patterned photoresist layer as a mask; and
removing the patterned photoresist layer without damaging the microlens array.

12. The process of claim 11, wherein the patterned photoresist layer is removed with oxygen plasma at a sufficiently low temperature and a sufficiently short RF time such that the microlens array is not damaged.

13. The process of claim 12, wherein the sufficiently low temperature is about 200° C. and the sufficiently short RF time is about 20 seconds.

14. The process of claim 8, wherein a top surface of the filling layer as formed is coplanar with a top surface of the insulating layer.

15. The process of claim 8, wherein a top surface of the filling layer as formed is or higher or lower than a top surface of the insulating layer.

16. The process of claim 15, wherein a height difference between top surfaces of the filling layer as formed and the insulating layer is no more than 20% of a depth of the pad opening.

17. The process of claim 8, wherein the filling layer comprises a material of the planarization layer.

18. The process of claim 17, wherein the filling layer and the planarization layer both comprise a negative photoresist material.

19. The process of claim 8, wherein the image sensor is a CMOS image sensor.
